(19) United States
(12) Patent Application Publication
(10) Pub. No.: US 2008/0072961 A1
(43) Pub. Date: Mar. 27, 2008

(54) Nanosized,dye-sensitized photovoltaic cell

(76) Inventors: Yong Liang, Gilbert, AZ (US); Jon J. Candelaria, Scottsdale, AZ (US); Kurt W. Eisenbeiser, Tempe, AZ (US); Yi Wei, Chandler, AZ (US)

Correspondence Address: INGRASSIA FISHER & LORENZ, P.C., 7150 E. CAMELBACK, STE. 325, SCOTTSDALE, AZ, 85251, US

(21) Appl. No.: 11/528,124

(22) Filed: Sep. 26, 2006

(51) Int. Cl. H01L 31/00

(52) U.S. Cl. 136/263

(57) ABSTRACT

A sensitized photovoltaic device (10) provides for a reduction of the charge recombination rate and charge transport time. The device (10) includes a first electrode (12) comprising a transparent conducting oxide and a plurality of carbon nanostructures (16) formed thereon. A first layer (18) is formed on the carbon nanostructure (16) and comprises a first conduction band level (44). A second layer (20) is formed on the first oxide (18) and comprises a second conduction band level (46) higher than the first conduction band level (44). A sensitizer (22) is formed on the second layer (20) and comprises a lowest unoccupied molecular orbital level (48) higher than the second conduction band level (46). An electrolyte (24) is positioned over the sensitizer (22), and a second electrode (26) comprising a transparent conducting oxide and a layer of catalyst is formed over the electrolyte (24).

### FIELD OF THE INVENTION

The present invention generally relates to sensitized photovoltaic cells and more particularly to a sensitized photovoltaic cell structure providing a reduction of the charge recombination rate and charge transport pass times.

### BACKGROUND OF THE INVENTION

Photovoltaic cells are well known for providing electricity from solar panels in both small scale distributed power systems and centralized megawatt scale power plants. Photovoltaic cells also have found applications in consumer electronics, e.g., portable electronic equipment such as cameras and watches. The cells operate without toxic or noise emissions, and require little maintenance. These cells may also be used as sensors for detection of a wide band of radiation.

Photovoltaic cells originally developed by the Bell Telephone Laboratories in the 1950's were, and most of the larger cells produced today are, silicon based due to the high quality silicon produced in large quantities by the semiconductor industry. Amorphous silicon may be found in low power sources in portable electronic devices, even though solar conversion efficiency is limited.

There are several key issues in providing a manufacturable photovoltaic cell for portable applications. These issues include charge generation, charge separation, charge transport, charge collection, stability, and manufacturing cost. Of these issues, charge transport and charge collection have previously been especially troublesome. The lifetime of a transitioning electron before recombining with a hole, in the case of silicon, is on the order of 1-30 ns; therefore, an electron must exit the recombination regime within that time frame if electricity is to be effectively generated. Conventional photovoltaic cells require a high degree of crystalline perfection to prevent undesirable recombination.

Dye-sensitized solar cells are well known wherein a Ruthenium-based dye applied to a semiconductor material receives a photon which injects an excited electron into a TiO₂ material and to an electrode. A hole is transferred from the dye through an electrolyte to another electrode. However, most of these dye-sensitized cells using a liquid electrolyte have issues with corrosiveness and leakage. Other approaches producing a non-liquid cell have met with limited success with power conversion efficiency.

U.S. patent publications 2005/0098204 and 2005/0098205 disclose a nanostructured template comprising a metal oxide or other oxide covered by two layers of a charge transfer material. However, no mention is made of the relative position of the conduction band and valence band levels of the two layers with respect to the recombination of photo-excited electron and hole. The relative position of the conduction band and valence band levels is important for injection of photo-electrons from dye molecules to the oxides and preventing electrons in oxides from recombining with holes in the dye molecule and electrolyte.

Accordingly, it is desirable to provide a dye-sensitized photovoltaic cell structure providing a reduction of the charge recombination rate and charge transport time. Furthermore, other desirable features and characteristics of the present invention will become apparent from the subsequent detailed description of the invention and the appended claims, taken in conjunction with the accompanying drawings and this background of the invention.

### BRIEF SUMMARY OF THE INVENTION

A sensitized photovoltaic device provides for a reduction of the charge recombination rate and charge transport time. The device includes a first electrode comprising a transparent conducting oxide and a plurality of carbon nanostructures grown thereon. A first oxide is formed on the carbon nanostructure and comprises a first conduction band level and valence band level. A second oxide is formed on the first oxide and comprises a second conduction band level and valence band level concomitantly higher than the first conduction band level and valence band level. A sensitized layer, e.g., a dye, is formed on the second oxide and comprises a lowest unoccupied molecular orbital (LUMO) level higher than the second conduction band level. An electrolyte is positioned over the dye, and a second electrode comprising a transparent conducting oxide and a layer of catalyst is formed over the electrolyte.

### BRIEF DESCRIPTION OF THE DRAWINGS

The present invention will hereinafter be described in conjunction with the following drawing figures, wherein like numerals denote like elements, and

FIG. 1 is a partial cross sectional view of a single electrode in accordance with an exemplary embodiment taken along the line 1-1 of FIG. 3;

FIG. 2 is a partial cross sectional view of a plurality of electrodes of FIG. 1 taken along the line 2-2 of FIG. 3;

FIG. 3 is a partial isometric view of a plurality of electrodes of FIG. 1; and

FIG. 4 is a chart illustrating the conduction and valence band, LUMO level and highest occupied molecular orbital (HOMO) level alignment of the layers comprising the electrode of FIG. 1.

### DETAILED DESCRIPTION OF THE INVENTION

The following detailed description of the invention is merely exemplary in nature and is not intended to limit the invention or the application and uses of the invention. Furthermore, there is no intention to be bound by any theory presented in the preceding background of the invention or the following detailed description of the invention.

Carbon nanotubes have demonstrated a significantly enhanced conductivity and robustness compared to the metallic materials used in the known art. A photovoltaic cell comprising a plurality of carbon nanostructures, i.e., carbon nanotubes, carbon nanowires, or carbon fibers covered by first and second oxides and a sensitized material, e.g., a dye, provides for improved efficiency by reducing the recombination rate of electrons and holes, and improving the transport of the photoexcited electrons through the first and second oxides. The structure described herein accomplishes five advantages over known art. First, the long nanostructures provide the required porosity/surface area needed for sufficient loading of sensitizer, e.g., dye, molecules, whether organic or inorganic, for optical absorption, and serve as an extended electrode (cathode) for electrons. Second, the first oxide layer immediately over the carbon nanostructure provides the required band alignment for separation of photo-excited electrons and holes. Third, the second oxide layer formed over the first oxide layer has a conduction band lying in between that of the first oxide layer and the LUMO (lowest unoccupied molecular orbital) of the dye molecules. The conduction and valence bands of the second oxide layer are concomitantly higher than that of the conduction and valence bands of the first oxide layer, thereby acting as a buffer layer between electrons in the first oxide layer and holes in the electrolyte or in the dye molecules. This prevents recombination of the electrons and holes without affecting the open circuit voltage due to its band alignment with the first oxide layer, second oxide layer, and the dye molecules. Fourth, the nanostructure/first oxide/second oxide structure provides a much shorter transport path (approximately tens of nanometers) for electrons over convention photovoltaic cells, thus increasing the charge extraction rate and further reducing electron-hole recombination. Fifth, the carbon nanostructure may serve as an internal mirror that not only reflects residual photons not absorbed by the dye molecules, and therefore may enhance the optical absorption of the dye molecules due to surface plasma effect, thus increasing the effective light absorption efficiency of the dye molecules.

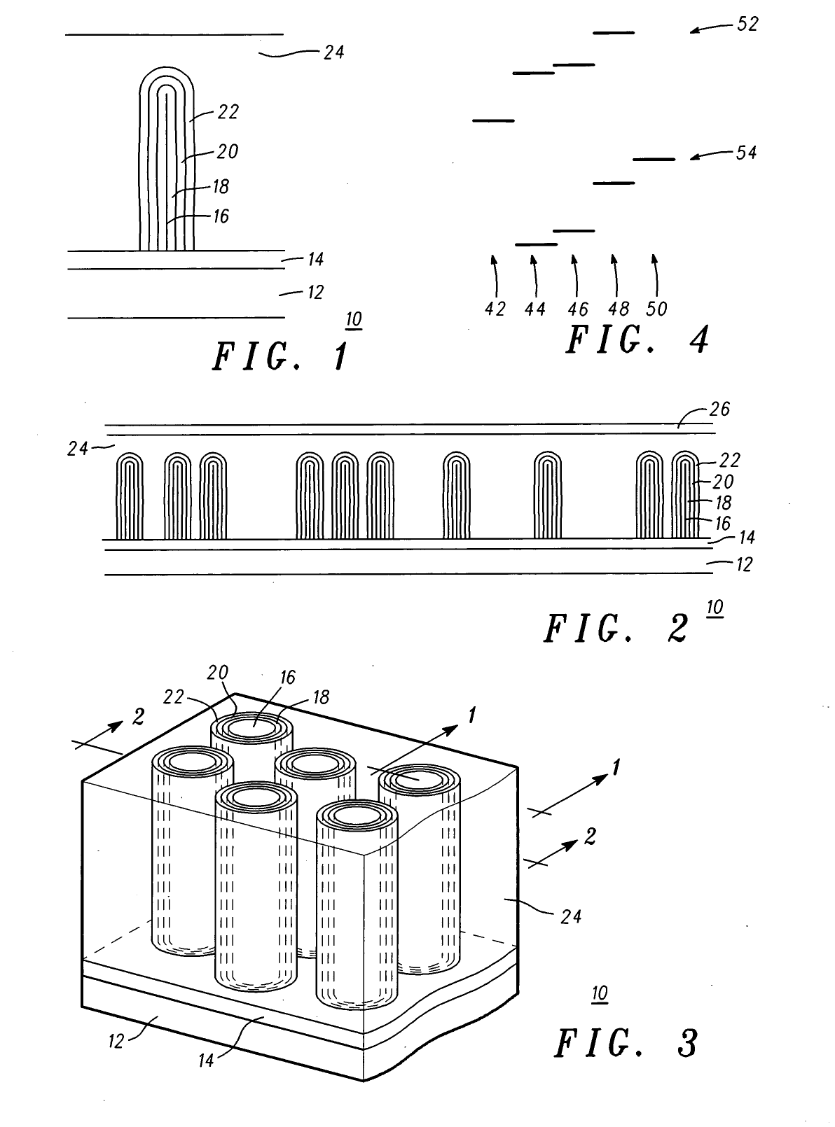

Referring to FIGS. 1 through 3, a photovoltaic cell 10 in accordance with an exemplary embodiment comprises an optional oxide layer 14 formed over a transparent conducting oxide 12. The transparent conducting oxide 12 may be formed on a transparent substrate such as glass or plastic (not shown) and may comprise flourine-doped tin oxide, indium oxide, for example, but preferably comprises indium tin oxide. The oxide layer 14 may comprise titanium oxide, zinc oxide, niobium oxide, vanadium oxide, magnesium oxide, hafnium oxide, zirconium oxide, strontium oxide, barium oxide, molybdenum oxide, tungsten oxide, ion oxide, cobalt oxide, nickel oxide, or certain combination of these oxides, but preferably comprises titanium oxide or TiO₂₋ₓ, where x can vary from 0 to 1.

Carbon nanostructures 16, having a length of 1 to 100 micrometers, but preferably approximately 10 micrometers, are grown on either the optional oxide layer 14 or the transparent conducting layer 12 generally in a non-uniform manner as is known in the industry from a plurality of catalysts such as Cobalt Aluminum nanoparticles formed overlaying the transparent conducting oxide 12 or the optional oxide layer 14. While only a few carbon nanostructures 16 are shown in FIGS. 2 and 3, it should be understood that millions or billions of nanostructures may be formed, using any known process. The carbon nanostructures 16 may form an organized pattern or an irregular arrangement. In addition to having carbon nanostructures directly grown on either the optional oxide layer 14 or the transparent conducting layer 12, these nanostructures can also be first grown on other substrates such as SiO₂, or in a suspended form, and then transferred onto the optional oxide layer 14 or the transparent conducting layer 12 using known transfer and bonding processes. The carbon nanostructures can be in the form of single-wall or multi-wall carbon nanotubes, nano-fibers, nanotubes bundles, nanowires, or a combination of these species.

A first layer 18 is formed to cover the carbon nanostructure 16, and a second layer 20 is formed to cover the first layer 18. Both of the first and second layers of 18, 20 are preferably formed by a dry atomic layer deposition, chemical vapor deposition, or solution processes through chemical route. The choice of the material for the first and second layers is interrelated. The second layer must have a conduction band higher than the conduction band of the first layer. The first layer 18 may comprise, for example, titanium oxide, niobium oxide, magnesium oxide, hafnium oxide, zirconium oxide, strontium oxide, barium oxide, molybdenum oxide, tungsten oxide, cobalt oxide, nickel oxide, or certain combinations of these oxides. The second layer 20 may comprise, for example, zinc oxide, or Mg₁₋ₓZnₓO_{y}, vanadium oxide, copper oxide, iron oxide, or combinations of these materials. Alternatively, layer 20 may also comprise semiconductors such as CdS, ZnS, ZnSe, ZnTe, CdTe, CdSe, PbS, GaAs, AlAs, GaN, AlN, InP, InSb, or a combination of these II-VI and III-V semiconductors. The thickness of the first layer 18 preferably comprises a thickness of between 10.0 and 100.0 nanometers, and the thickness of the second layer 20 preferably comprises a thickness of approximately 1.0 to 10.0 nanometers.

A dye layer 22 is formed over the second layer 20, preferably by, but not limited to, immersing the structure 10 in a solution of dye complexes such as ruthenium complexes where one of the ligands is typically 4,4′-dicarboxy-2,2′-bipyridyl. The time of immersion can vary from a few minutes to a few days depending on temperature and solution concentration.

An electrolyte material 24 is formed over the dye layer 22. The electrolyte material preferably comprises a layer of a polymer material since it is a condensed material and not subject to leaking. Alternatively, the electrolyte material 24 may comprise, for example, a gel comprising a mixture of iodine and organic material, or a solution comprising iodine salt and organic solvent. An electrode 26 is formed over a catalyst layer 24. The catalyst 24 comprises Pt, carbon, or a combination of the two.

Referring to FIG. 4, the charge transport levels of the carbon nanostructure level 42, first layer level 44, second layer level 46, dye level 48, and electrolyte level 50, each for the conduction band or LUMO bands 52 and the valence or HOMO (highest occupied molecular orbital) bands 54 are shown. When photons pass through the transparent conducting oxide 12, they are absorbed by the dye material 22 striking a molecule, causing an electron in the dye material 22 to migrate to layer 20 having a band layer 46. Note that any photons striking the carbon nanostructure 16 will reflect to the dye material 22. The electron continues its migration to the layer 18 having a band layer 44, to the carbon nanostructure 16 having a band layer 42, and to the transparent conducting oxide 12 (electrode). As the electron migrates from the dye material 22, a hole migrates in the reverse direction along the HOMO bands to the electrolyte 24 and the electrode 26. Since the distances across (thickness) the oxide layers are small, on the order of about 10 to 100 nm, the time the electron is in transit is short, which reduces the likelihood of recombination with the hole. And, since the electron passes through the band gap level 46 of the layer 20 and the band gap level 44 of the layer 18, the likelihood of recombination is reduced further because the electron would have to “jump” the additional energy barrier to recombine with its hole. Likewise, the hole in dye molecules or the electrolyte is difficult to recombine with the electron in layer 18 or carbon nanostructure because the presence of the energy barrier between layer 18 and 20.

While at least one exemplary embodiment has been presented in the foregoing detailed description of the invention, it should be appreciated that a vast number of variations exist. It should also be appreciated that the exemplary embodiment or exemplary embodiments are only examples, and are not intended to limit the scope, applicability, or configuration of the invention in any way. Rather, the foregoing detailed description will provide those skilled in the art with a convenient road map for implementing an exemplary embodiment of the invention, it being understood that various changes may be made in the function and arrangement of elements described in an exemplary embodiment without departing from the scope of the invention as set forth in the appended claims.

1. A structure comprising:
a first transparent conducting material;
a carbon nanostructure formed over the first transparent conducting material;
a first layer formed over the carbon nanostructure and having a first conduction band level;
a second layer formed over the first layer and having a second conduction band level higher than the first conduction band level; and
a sensitizer formed over the second layer and having a lowest unoccupied molecular orbital level higher than the second conduction band level.

2. The structure of claim 1 wherein the carbon nanostructure comprises one of a carbon nanotube, a nanofiber, or a carbon nanowire.

3. The structure of claim 1 wherein the difference between the first conduction band level and the second conduction band level is less than 0.5 eV.

4. The structure of claim 3 wherein the difference between the second conduction band level and the lowest unoccupied molecular orbital level is less than 0.6 eV.

5. The structure of claim 1 wherein the differences between the first conduction band level and the second conduction band level, and between the second conduction band level and the lowest unoccupied molecular orbital level are substantially the same.

6. The structure of claim 1 further comprising an electrolyte positioned over the sensitizer.

7. The structure of claim 6 further comprising a second transparent conducting oxide formed over the electrolyte.

8. The structure of claim 1 wherein the carbon nanostructure is transferred from another material to the first transparent conducting oxide.

9. The photovoltaic device of claim 1 wherein the sensitizer comprises an inorganic material.

10. The photovoltaic device of claim 1 wherein the sensitizer comprises a dye.

11. A photovoltaic device comprising:
a first electrode comprising a conducting material;
a plurality of carbon nanostructures formed over the first conducting material;
a first layer formed on each of the carbon nanostructures and having a first conduction band level;
a second layer formed on the first layer and having a second conduction band level higher than the first conduction band level;
a sensitizer formed on the second layer and having a lowest unoccupied molecular orbital level higher than the second conduction band level;
an electrolyte positioned over the sensitizer; and
a second electrode comprising a conducting material formed over the electrolyte, wherein at least one of the first and second electrodes are transparent.

12. The photovoltaic device of claim 11 wherein the carbon nanostructure comprises one of a carbon nanotube, a nanofiber, or a carbon nanowire.

13. The photovoltaic device of claim 11 wherein the difference between the first conduction band level and the second conduction band level is less than 0.5 eV.

14. The photovoltaic device of claim 13 wherein the difference between the second conduction band level and the lowest unoccupied molecular orbital level is less than 0.6 eV.

15. The photovoltaic device of claim 11 wherein the carbon nanostructure is transferred from another material to the first conducting material.

16. The photovoltaic device of claim 11 wherein the sensitizer comprises an inorganic material.

17. The photovoltaic device of claim 11 wherein the sensitizer comprises a dye.

18. A method for producing an electron flow in a photovoltaic device, comprising:
receiving a photon through a transparent electrode;
passing the photon through an electrolyte;
striking a molecule within a sensitizer layer to excite an electron, the sensitizer layer having an energy gap level;
migrating the electron to a first layer having a first band gap level;
migrating the electron to a second layer having a second band gap level;
migrating the electron to a carbon nanostructure;
migrating the electron to an electrode;
wherein the energy gap level, and first and second band gap levels, respectively, have a descending energy value.

19. The method of claim 18 wherein the migrating the electron to the first layer comprises migrating to the first band gap level having a value less that 0.6 eV less than the energy gap level of the sensitizer layer.

20. The method of claim 19 wherein the migrating the electron to the second layer comprises migrating to the second band gap level having a value less that 0.5 eV less than the first band gap level.
